(19) United States
(12) Patent Application Publication
(10) Pub. No.: US 2008/0237751 A1
(43) Pub. Date: Oct. 2, 2008

(54) CMOS Structure and method of manufacturing same

(76) Inventors: Uday Shah, Portland, OR (US); Brian S. Doyle, Portland, OR (US); Jack T. Kavalieros, Portland, OR (US); Willy Rachmady, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/731,163

(22) Filed: Mar. 30, 2007

(51) Int. Cl. H01L 21/8238

(52) U.S. Cl. 257/412; 438/199; 257/E21.632

(57) ABSTRACT

A CMOS structure includes a substrate (110, 310), an electrically insulating layer (120, 320) over the substrate, NMOS (130, 330) and PMOS (140, 340) semiconducting structures over the electrically insulating layer, and a dielectric layer (150, 350) having first (151, 351) and second (152, 352) portions over, respectively, the NMOS and PMOS semiconducting structures. The NMOS and PMOS semiconducting structures have, respectively, a first height (135, 335) and a second height (145, 345). The CMOS structure further includes a first electrically conducting layer (160, 360) over the first portion of the dielectric layer, a second electrically conducting layer (170, 370) over the second portion of the dielectric layer and thicker than the first electrically conducting layer, a first polysilicon layer (180, 780) over the first electrically conducting layer, and a second polysilicon layer (190, 790) over the second electrically conducting layer and thinner than the first polysilicon layer.

### FIELD OF THE INVENTION

The disclosed embodiments of the invention relate generally to transistors, and relate more particularly to complementary metal-oxide semiconductor (CMOS) transistors.

### BACKGROUND OF THE INVENTION

Polysilicon in semiconductor devices has different etch rates depending on the type of material on which the polysilicon is located. Etch rate differences of up to 30% have been observed in single metal-oxide semiconductor (MOS) wafers with identical polysilicon type and thickness. For CMOS structures, this etch-rate variation means that polysilicon over an N-type MOS (NMOS) device will etch at a different (faster) rate than will polysilicon over a P-type MOS (PMOS) device. This leads to problems such as sidewall notching and dielectric breakthrough. In the case of tri-gate structures, the etch-rate difference may also lead to significant fin damage in the NMOS regions. These and other problems may arise because the fins or other structures are exposed early during polysilicon etch. While the PMOS polysilicon continues to etch because of a slower etch rate compared to the NMOS polysilicon, the NMOS metal starts to come under attack. In some cases, a particular structural layout causes enhanced etching to occur in the fin regions right next to the polysilicon gates, thus weakening the metal and the dielectric material in this region.

A critical part of at least some tri-gate CMOS device manufacturing flows is an over etch step (employed to clean up polysilicon stringers in a 3-D topography) because the over etch step defines the gate length (LG) of two out of the three gates, and problems arising from the over etch step can be the leading cause of device performance degradation. At some point during the over etch step, however, the PMOS metal will be reached for the first time while at that same time in the NMOS regions, the dielectric material will begin to be etched. In some extreme cases even the underlying silicon in the NMOS region is exposed to the etch chemistry by the time the over etch first reaches the PMOS metal.

Metal patterning of the PMOS metal (often requiring greater than a 50:1 selectivity of metal to dielectric material) is a most difficult challenge in the event that a dry etch patterning solution is needed because the thin metal on top of the fins defining the NMOS transistor is etched almost instantaneously during the metal etch. In some cases, as explained above, the metal was already etched during the polysilicon etch. In this happens the dielectric material on these NMOS fins is exposed for the entirety of the PMOS metal etch and can be significantly damaged.

Furthermore, a hard mask etch requires a significant over etch because of the variation in thickness due to topography. This variation often causes polysilicon micromasking if insufficient hard mask is etched. But the amount of over etch can be 20-25% and this can cause unwanted notches in the polysilicon sidegates. Accordingly, there exists a need for a way to pattern tri-gate and other CMOS structures that enables a uniform exposure of NMOS and PMOS fins during polysilicon gate etch, thus allowing multiple step gate patterning techniques such as those currently used to pattern CMOS metal gates.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a CMOS structure according to an embodiment of the invention;

FIG. 2 is a flowchart illustrating a method of manufacturing a CMOS structure according to an embodiment of the invention; and

FIGS. 3-7 are cross-sectional views of a CMOS structure at various particular points in its manufacturing process according to embodiments of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a CMOS structure comprises a substrate, an electrically insulating layer over the substrate, an NMOS semiconducting structure and a PMOS semiconducting structure located over the electrically insulating layer, and a dielectric layer having a first portion over the NMOS semiconducting structure and a second portion over the PMOS semiconducting structure. The electrically insulating layer has a first surface. The NMOS semiconducting structure has a first height and the PMOS semiconducting structure has a second height that is approximately equal to the first height. The CMOS structure further comprises a first electrically conducting layer (having a first thickness) over the first portion of the dielectric layer, a second electrically conducting layer (having a second thickness) over the second portion of the dielectric layer, a first polysilicon layer (having a third thickness) over the first electrically conducting layer, and a second polysilicon layer (having a fourth thickness) over the second electrically conducting layer. The first thickness is less than the second thickness and the third thickness is greater than the fourth thickness.

The “endpoint of polysilicon” is the time corresponding to the first exposure of metal almost everywhere on the substrate during poly-silicon etch in current conventional CMOS tri-gate stacks. As mentioned above, polysilicon etches at different rates over NMOS and PMOS devices due to the nature of the various gate metal materials. This etch-rate difference makes it very likely that in a CMOS device under existing manufacturing techniques, only one but not both of NMOS and PMOS metals are exposed at endpoint of polysilicon, making subsequent patterning of the device problematic. In contrast, embodiments of the present invention enable the simultaneous exposure of NMOS and PMOS fins during polysilicon gate etch (at endpoint of polysilicon) and thus allow multiple-step gate patterning techniques.

The severe 3-D topography of tri-gate devices often leads to line width variation, i.e., narrowing and widening of polysilicon lines on and off the silicon fin. More specifically, the hard mask that is deposited over the large topography polysilicon layer is often not conformal, but can be almost thirty percent greater than the deposited amount in the region between two silicon fins because of the crease formed in that area due to the difference in NMOS and PMOS metal thicknesses. This variation in hard mask thickness gives rise to non-uniformity in lithography, causing the resist lines to narrow and widen. Embodiments of the invention enable such line width variation to be minimized by providing hard masks of uniform thickness over transistors. Additionally, having a hard mask of uniform thickness minimizes the amount of hard mask over etch required to prevent micromasking of polysilicon. Still further, embodiments of the invention enable N-type and P-type metals with significant thickness variations to be incorporated into a CMOS process flow.

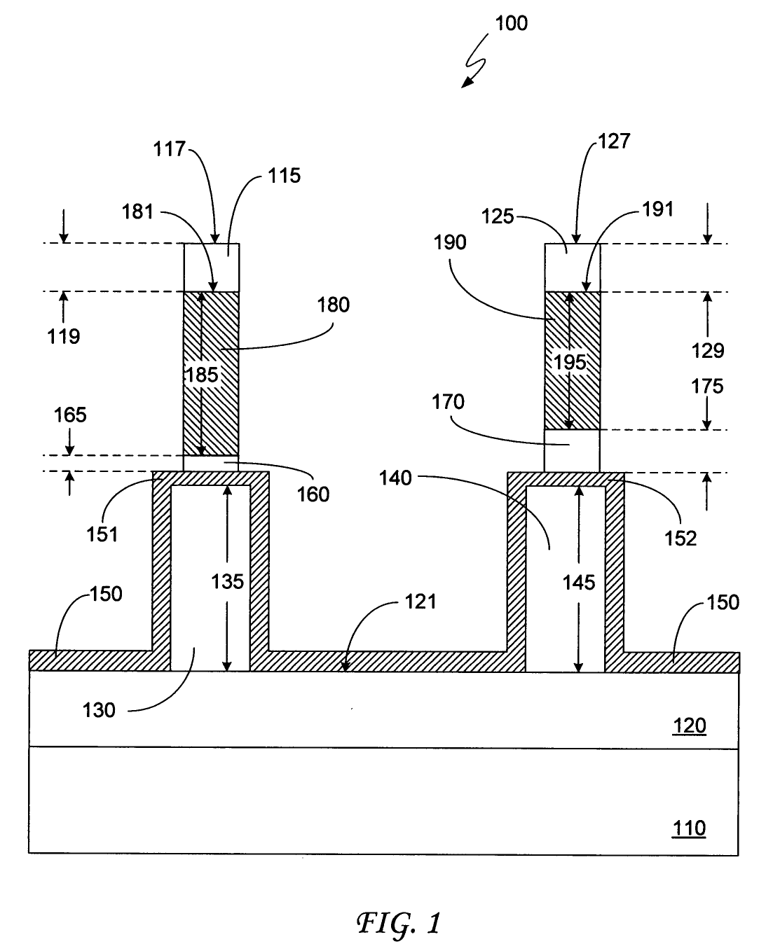

Referring now to the drawings, FIG. 1 is a cross-sectional view of a CMOS structure 100 according to an embodiment of the invention. As illustrated in FIG. 1, CMOS structure 100 comprises a substrate 110, an electrically insulating layer 120 over substrate 110, and an NMOS semiconducting structure 130 and a PMOS semiconducting structure 140 located over electrically insulating layer 120. Electrically insulating layer 120 has a surface 121. As an example, electrically insulating layer 120 can be a layer of oxide, nitride, or the like.

As another example, NMOS semiconducting structure 130 and PMOS semiconducting structure 140 can be silicon fins that form a part of a tri-gate semiconducting device. More specifically, in one embodiment, NMOS semiconducting structure 130 is a portion (such as a raised source/drain structure) of a tri-gate device such as a tri-gate transistor. In the same or another embodiment, PMOS semiconducting structure 140 is a portion (such as a raised source/drain structure) of a different tri-gate transistor or other tri-gate device. NMOS semiconducting structure 130 has a height 135. PMOS semiconducting structure 140 has a height 145 that is approximately equal to height 135. Heights 135 and 145 are measured from surface 121.

CMOS structure 100 further comprises a dielectric layer 150 having a portion 151 over NMOS semiconducting structure 130 and a portion 152 over PMOS semiconducting structure 140. CMOS structure 100 still further comprises an electrically conducting layer 160 over portion 151 of dielectric layer 150, an electrically conducting layer 170 over portion 152 of dielectric layer 150, a polysilicon layer 180 over electrically conducting layer 160, and a polysilicon layer 190 over electrically conducting layer 170. As an example, electrically conducting layers 160 and 170 can be metal gate electrodes comprising a metal such as tantalum or titanium or their nitrides, tantalum nitride, titanium nitride, or the like.

Electrically conducting layer 160 has a thickness 165, and electrically conducting layer 170 has a thickness 175. Thickness 175 is greater—in some embodiments as much as approximately thirty percent greater—than thickness 165. This difference in thicknesses is chosen based on the etch rate difference between NMOS polysilicon and PMOS polysilicon, with the goal being to have NMOS and PMOS gate metal simultaneously exposed at endpoint of polysilicon.

Polysilicon layer 180 has a surface 181 and a thickness 185, and polysilicon layer 190 has a surface 191 and a thickness 185. Thickness 185 is greater than thickness 195. In one embodiment, surface 181 and surface 191 are each substantially parallel to surface 121. As an example, surfaces 181 and 191 may be made substantially parallel to surface 121 using a chemical mechanical polishing (CMP) operation or the like.

In one embodiment, dielectric layer 150 comprises a material having a high dielectric constant. (Such a material is referred to herein as a “high-k material.”) Silicon dioxide, which has been widely used as a gate dielectric, has a dielectric constant (k) of approximately 3.9. Air, which is used as a scale reference point, has a dielectric constant defined as 1. Accordingly, any material having a dielectric constant greater than about 10 likely qualifies as, and is referred to herein as, a high-k material. As an example, the high-k material used in an embodiment of CMOS structure 100 may be a hafnium-based, a zirconium-based, or a titanium-based dielectric material that may have a dielectric constant of at least approximately 20. In a particular embodiment the dielectric material is hafnium oxide having a dielectric constant of between approximately 20 and approximately 40. In a different particular embodiment the dielectric material is zirconium oxide having a dielectric constant of between approximately 20 and approximately 40.

Referring still to FIG. 1, CMOS structure 100 further comprises a hard mask 115 over polysilicon layer 180 and a hard mask 125 over polysilicon layer 190. Hard mask 115 has a surface 117 and a thickness 119, while hard mask 125 has a surface 127 and a thickness 129. In one embodiment, surface 117 and surface 127 are substantially equidistant from surface 121. In other words, in one embodiment surface 117 and surface 127 each rise to substantially the same height, and reach substantially the same level, above surface 121. In the same or another embodiment, thickness 129 is approximately equal to thickness 119, meaning that hard masks 115 and 125 are of substantially uniform thickness. As mentioned above, such uniform hard mask thickness minimizes the amount of hard mask over etch required to prevent micromasking of polysilicon. CMOS devices without the uniform hard mask thickness enabled by embodiments of the invention can require over etch amounts as large as 20-25% in order to prevent polysilicon micromasking. As known to those of ordinary skill in the art, hard mask over etches of this magnitude can cause notches in polysilicon sidegates.

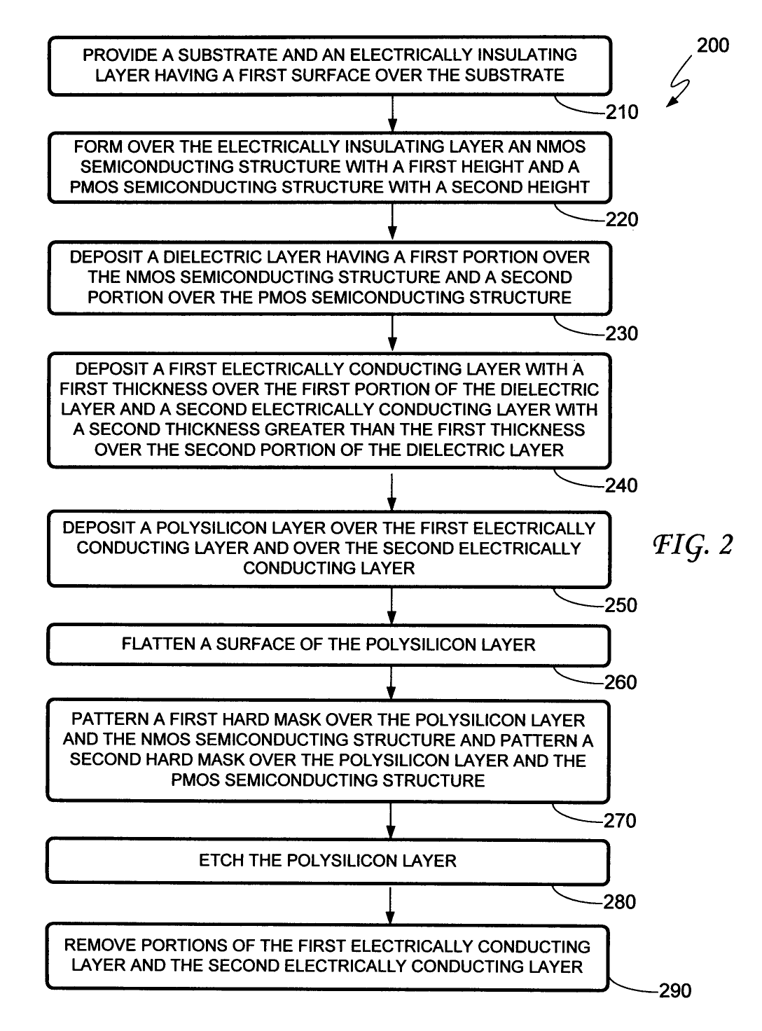

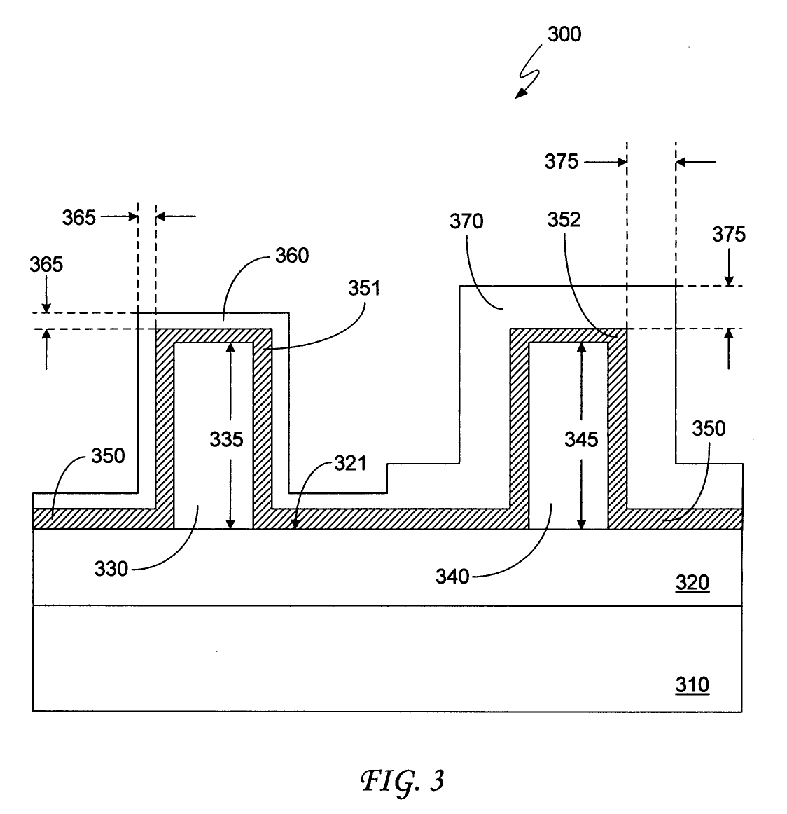

FIG. 2 is a flowchart illustrating a method 200 of manufacturing a CMOS structure according to an embodiment of the invention. A step 210 of method 200 is to provide a substrate and an electrically insulating layer having a first surface over the substrate. As an example, the substrate, the electrically insulating layer, and the first surface can be similar to, respectively, substrate 110, electrically insulating layer 120, and surface 121, all of which are shown in FIG. 1. As another example, the substrate and the electrically insulating layer can be similar to, respectively, a substrate 310 and an electrically insulating layer 320, both of which are first shown in FIG. 3.

FIG. 3 is a cross-sectional view of a CMOS structure 300 at a particular point in its manufacturing process according to an embodiment of the invention. Specifically, in one embodiment FIG. 3 may depict CMOS structure 300 at a time following the performance of at least step 210 of method 200 or a corresponding or similar step of a different method according to an embodiment of the invention. As mentioned above, FIG. 3 illustrates substrate 310 and electrically insulating layer 320 that respectively can be similar to substrate 110 and electrically insulating layer 120 that are shown in FIG. 1. As further illustrated in FIG. 3, electrically insulating layer 320 has a surface 321.

A step 220 of method 200 is to form over the electrically insulating layer an NMOS semiconducting structure with a first height and a PMOS semiconducting structure with a second height. As an example, the NMOS semiconducting structure and the first height can be similar to, respectively, NMOS semiconducting structure 130 and height 135, both of which are shown in FIG. 1. As another example, the PMOS semiconducting structure and the second height can be similar to, respectively, PMOS semiconducting structure 140 and height 145, both of which are also shown in FIG. 1. As a further example, the NMOS semiconducting structure, the first height, the PMOS semiconducting structure, and the second height can also be similar to, respectively, an NMOS semiconducting structure 330, a height 335, a PMOS semiconducting structure 340, and a height 345, all of which are first shown in FIG. 3.

A step 230 of method 200 is to deposit a dielectric layer having a first portion over the NMOS semiconducting structure and a second portion over the PMOS semiconducting structure. As an example, the dielectric layer, the first portion, and the second portion can be similar to, respectively, dielectric layer 150, portion 151, and portion 152, all of which are shown in FIG. 1. As another example, the dielectric layer, the first portion, and the second portion can be similar to, respectively, a dielectric layer 350, a portion 351 of dielectric layer 350, and a portion 352 of dielectric layer 350, all of which are first shown in FIG. 3.

A step 240 of method 200 is to deposit a first electrically conducting layer with a first thickness over the first portion of the dielectric layer and a second electrically conducting layer with a second thickness greater than the first thickness over the second portion of the dielectric layer. In one embodiment, step 240 comprises causing the second thickness to be as much as thirty percent greater than the first thickness. As mentioned above, the difference in thicknesses is chosen based on the etch rate difference between NMOS polysilicon and PMOS polysilicon, with the goal being to have NMOS and PMOS gate metal simultaneously exposed at endpoint of polysilicon. The thicknesses and material types are chosen based on the required work function of the individual MOS, with a thickness range in one embodiment of between approximately 0.5 nanometers and approximately 50 nanometers.

As an example, the first electrically conducting layer, the first thickness, the second electrically conducting layer, and the second thickness can be similar to, respectively, electrically conducting layer 160, thickness 165, electrically conducting layer 170, and thickness 175, all of which are shown in FIG. 1. As another example, the first electrically conducting layer, the first thickness, the second electrically conducting layer, and the second thickness can be similar to, respectively, an electrically conducting layer 360, a thickness 365, an electrically conducting layer 370, and a thickness 375, all of which are features of CMOS structure 300 that are first shown in FIG. 3.

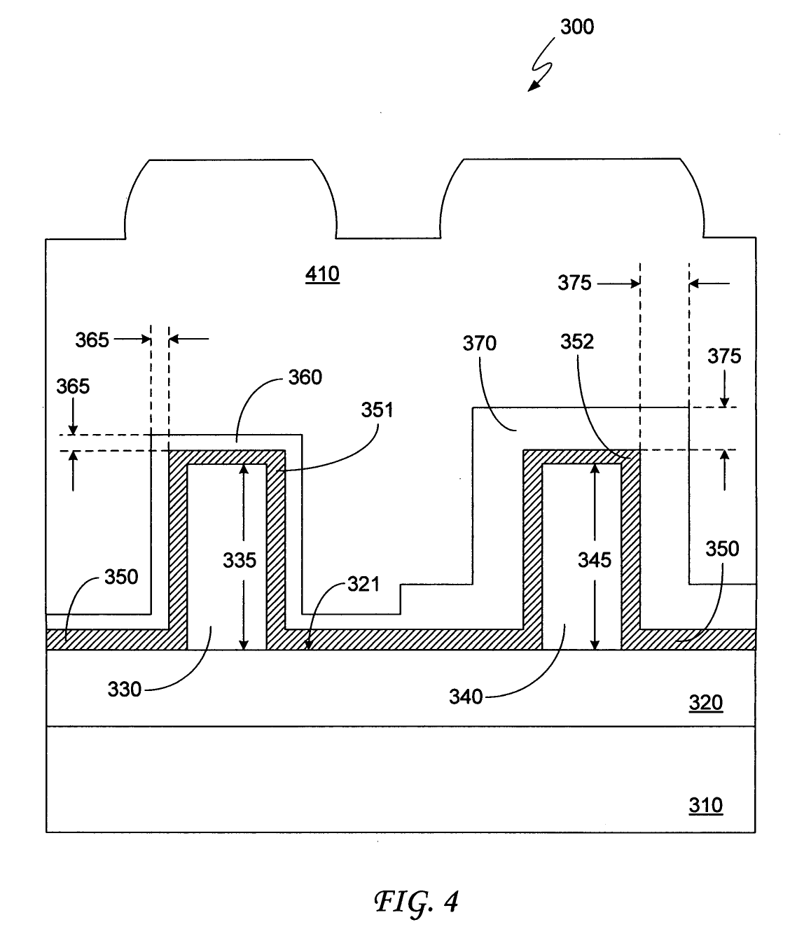

A step 250 of method 200 is to deposit a polysilicon layer over the first electrically conducting layer and over the second electrically conducting layer. As an example, portions of the polysilicon layer can be similar to polysilicon layers 180 and 190, both of which are shown in FIG. 1. As another example, the polysilicon layer can be similar to a polysilicon layer 410 that is shown in FIG. 4.

FIG. 4 is a cross-sectional view of CMOS structure 300 at a particular point in its manufacturing process according to an embodiment of the invention. Specifically, in one embodiment FIG. 4 may depict CMOS structure 300 at a time following the performance of at least steps 210, 220, 230, 240, and 250 of method 200, or of corresponding or similar steps of a different method according to an embodiment of the invention. As mentioned above, FIG. 4 illustrates polysilicon layer 410, portions of which, perhaps after further processing steps, can be similar to polysilicon layers 180 and 190 that are shown in FIG. 1.

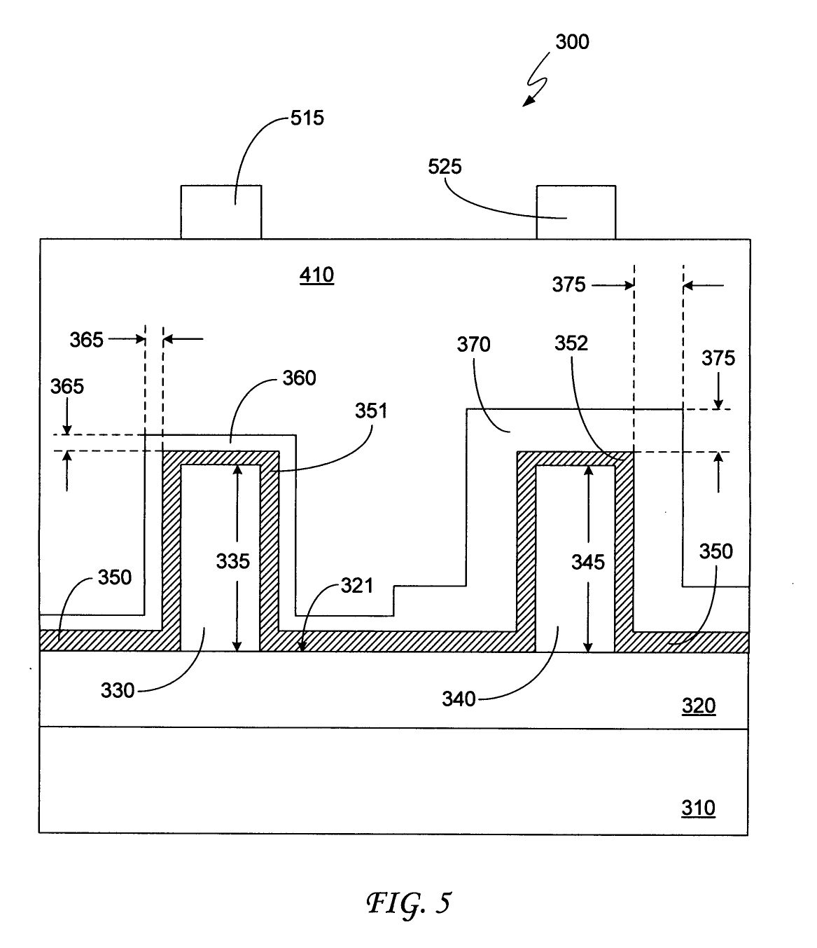

A step 260 of method 200 is to flatten a surface of the polysilicon layer. As an example, step 260 may comprise performing a CMP operation or the like. As another example, following the performance of at least step 260 of method 200, or of a corresponding or similar step of a different method according to an embodiment of the invention, CMOS structure 300 may have an appearance similar to that shown in FIG. 5. (The hard mask features shown in FIG. 5 and to be discussed below may not be present in CMOS structure 300 until after the performance of a subsequent step in method 200 or another method according to an embodiment of the invention.)

A step 270 of method 200 is to pattern a first hard mask over the polysilicon layer and the NMOS semiconducting structure and pattern a second hard mask over the polysilicon layer and the PMOS semiconducting structure, e.g., according to techniques known in the art. As an example, the first hard mask and the second hard mask can be similar to, respectively, hard mask 115 and hard mask 125, both of which are shown in FIG. 1. As another example, the first and second hard masks can be similar to, respectively, a hard mask 515 and a hard mask 525, both of which are first shown in FIG. 5.

FIG. 5 is a cross-sectional view of CMOS structure 300 at a particular point in its manufacturing process according to an embodiment of the invention. Specifically, in one embodiment FIG. S may depict CMOS structure 300 at a time following the performance of at least steps 210, 220, 230, 240, 250, 260, and 270 of method 200, or of corresponding or similar steps of a different method according to an embodiment of the invention. As mentioned above, FIG. S illustrates hard mask 515 and hard mask 525 that respectively can be similar to hard mask 115 and hard mask 125 that are shown in FIG. 1.

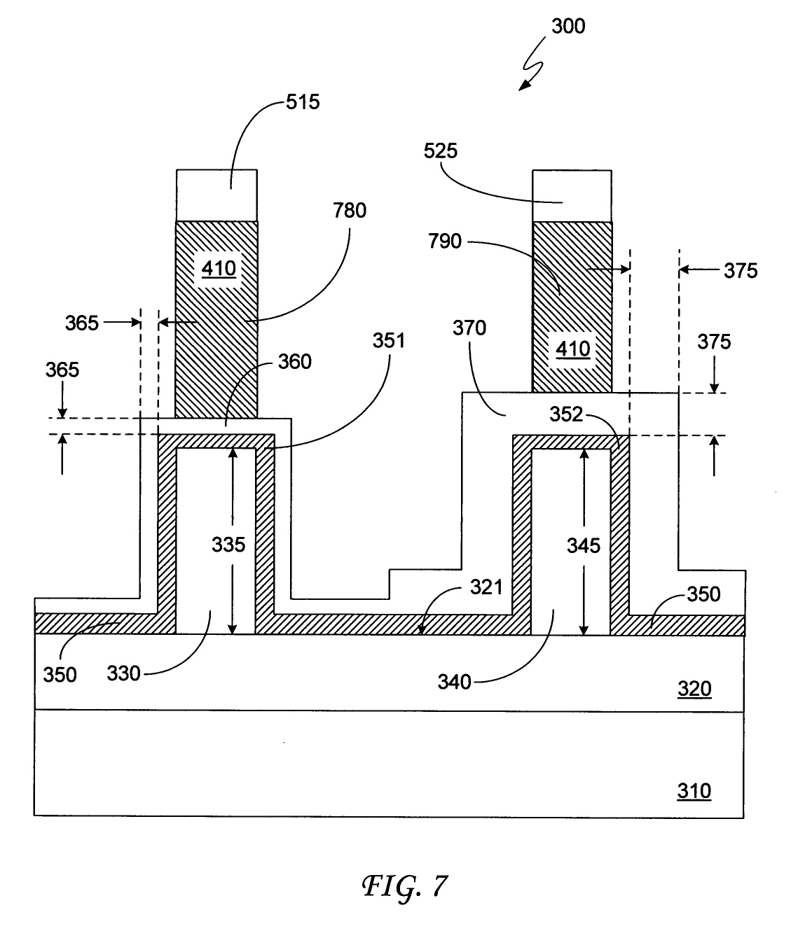

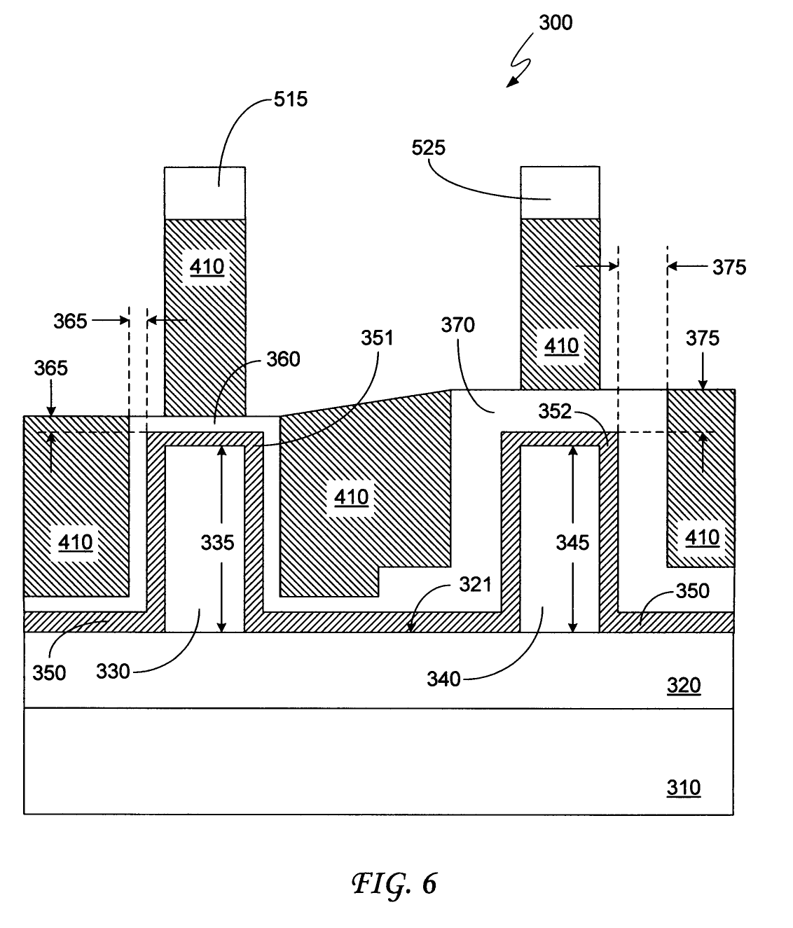

A step 280 of method 200 is to etch the polysilicon layer. In at least one embodiment the etching is done in multiple sub-steps, with certain sub-steps using etch chemistries that are different from the etch chemistries used in certain other sub-steps. As an example, after a first etching sub-step CMOS structure 300 may have an appearance similar to what is illustrated in FIG. 6, and after a subsequent etching sub-step may have an appearance similar to what is illustrated in FIG. 7.

It should be noted that FIG. 6 depicts what has been referred to herein as “endpoint of silicon,” and further noted that at this stage both NMOS and PMOS gate metals are simultaneously exposed. Still further, it should be noted that following step the second etching sub-step discussed above (or another etching sub-step) the only remaining portions of polysilicon layer 480 are a polysilicon layer 780 that may be similar to polysilicon layer 180 (shown in FIG. 1) and a polysilicon layer 790 that may be similar to polysilicon layer 190 (also shown in FIG. 1).

A step 290 of method 200 is to remove portions of the first electrically conducting layer and the second electrically conducting layer. As an example, this removal may be accomplished using an etching procedure according to techniques that are known in the art. As another example, following the performance of step 280, CMOS structure 300 may have an appearance similar to that of CMOS structure 100 as illustrated in FIG. 1. In other words, in one embodiment of the invention FIGS. 3-7 depict various stages during a manufacturing process of CMOS structure 100 (temporarily labeled CMOS structure 300 during the intermediate manufacturing steps), and FIG. 1 depicts the CMOS structure 100 after the described manufacturing steps have all been performed.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the CMOS structure and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A CMOS structure comprising:
a substrate;
an electrically insulating layer over the substrate, the electrically insulating layer having a first surface;
an NMOS semiconducting structure located over the electrically insulating layer and having a first height, and a PMOS semiconducting structure located over the electrically insulating layer and having a second height that is approximately equal to the first height;
a dielectric layer having a first portion over the NMOS semiconducting structure and a second portion over the PMOS semiconducting structure;
a first electrically conducting layer over the first portion of the dielectric layer and having a first thickness;
a second electrically conducting layer over the second portion of the dielectric layer and having a second thickness;
a first polysilicon layer over the first electrically conducting layer and having a third thickness; and
a second polysilicon layer over the second electrically conducting layer and having a fourth thickness;
wherein:
the first thickness is less than the second thickness; and
the third thickness is greater than the fourth thickness.

2. The CMOS structure of claim 1 wherein:
the first polysilicon layer has a second surface;
the second polysilicon layer has a third surface; and
the second surface and the third surface are substantially parallel to the first surface.

3. The CMOS structure of claim 2 wherein:
the NMOS semiconducting structure is a portion of a first tri-gate device; and
the PMOS semiconducting structure is a portion of a second tri-gate device.

4. The CMOS structure of claim 3 wherein:
the first tri-gate device is a first tri-gate transistor; and
the second tri-gate device is a second tri-gate transistor.

5. The CMOS structure of claim 2 wherein:
the second thickness is as much as thirty percent greater than the first thickness.

6. The CMOS structure of claim 2 further comprising:
a first hard mask over the first polysilicon layer having a fourth surface and a fifth thickness; and
a second hard mask over the second polysilicon layer having a fifth surface and a sixth thickness that is approximately equal to the fifth thickness, wherein the fourth surface and the fifth surface are substantially equidistant from the first surface.

7. A method of manufacturing a CMOS structure, the method comprising:
providing a substrate and an electrically insulating layer over the substrate, the electrically insulating layer having a first surface;
forming over the electrically insulating layer an NMOS semiconducting structure with a first height and a PMOS semiconducting structure with a second height that is approximately equal to the first height;
depositing a dielectric layer having a first portion over the NMOS semiconducting structure and a second portion over the PMOS semiconducting structure;
depositing a first electrically conducting layer with a first thickness over the first portion of the dielectric layer and a second electrically conducting layer with a second thickness greater than the first thickness over the second portion of the dielectric layer;
depositing a polysilicon layer over the first electrically conducting layer and over the second electrically conducting layer;
flattening a surface of the polysilicon layer;
patterning a first hard mask over the polysilicon layer and the NMOS semiconducting structure and patterning a second hard mask over the polysilicon layer and the PMOS semiconducting structure;
etching the polysilicon layer; and
removing portions of the first electrically conducting layer and the second electrically conducting layer.

8. The method of claim 7 wherein:
forming the NMOS semiconducting structure comprises forming a portion of a first tri-gate device; and
forming the PMOS semiconducting structure comprises forming a portion of a second tri-gate device.

9. The method of claim 8 wherein:
forming the portion of the first tri-gate device comprises forming a portion of a first tri-gate transistor; and
forming the portion of the second tri-gate device comprises forming a portion of a second tri-gate transistor.

10. The method of claim 7 wherein:
depositing the first electrically conducting layer and the second electrically conducting layer comprise causing the second thickness to be as much as thirty percent greater than the first thickness.
